(19) United States
(12) Patent Application Publication
(10) Pub. No.: US 2026/0291450 A1
(43) Pub. Date: Sep. 24, 2026

(54) POWER AMPLIFIER CIRCUIT

(71) Applicant: Murata Manufacturing Co., Ltd., Nagaokakyo-shi (JP)

(72) Inventors: Makoto ITOU, Nagaokakyo-shi (JP); Makoto TABEI, Nagaokakyo-shi (JP)

(21) Appl. No.: 19/672,908

(22) Filed: May 11, 2026

Related U.S. Application Data
(63) Continuation of application No. PCT/JP2024/041197, filed on Nov. 20, 2024.

(30) Foreign Application Priority Data
Nov. 22, 2023 (JP) 2023-198553

(51) Int. Cl. H03F 3/21; H03F 1/22

(52) U.S. Cl. CPC H03F 3/211; H03F 1/223; H03F 2200/451; H03F 2200/507

(57) ABSTRACT

To keep characteristics of a power amplifier circuit with no influence on cost. The power amplifier circuit includes amplifier units of multiple stages. The power amplifier circuit includes a first amplifier unit that amplifies a radio-frequency signal that is inputted, a second amplifier unit that amplifies an output from the first amplifier unit, and a switch portion provided on a power supply path to the first amplifier unit. Power is supplied to the first amplifier unit via the switch portion. The switch portion sets power supply to the first amplifier unit to ON or OFF. The power is directly supplied to the second amplifier unit not via the switch portion.

### CROSS REFERENCE TO RELATED APPLICATION

This is a continuation of International Application No. PCT/JP2024/041197 filed on November 20, 2024 which claims priority from Japanese Patent Application No. 2023-198553 filed on November 22, 2023. The contents of these applications are incorporated herein by reference in their entireties.

### BACKGROUND OF THE DISCLOSURE

### FIELD OF THE DISCLOSURE

The present disclosure relates to a power amplifier circuit.

### DESCRIPTION OF THE RELATED ART

A power amplifier circuit that amplifies a radio-frequency signal using amplifiers of multiple stages that are cascode-connected to each other has heretofore been known (for example, Japanese Unexamined Patent Application Publication No. 9-8675). In Japanese Unexamined Patent Application Publication No. 9-8675, power supply voltage is supplied to each of the amplifiers of multiple stages via a switch.

### BRIEF SUMMARY OF THE DISCLOSURE

It is possible to set power supply to the amplifier of each stage to ON or OFF by turning on or off the switch, as in Japanese Unexamined Patent Application Publication No. 9-8675, to prevent breakdown of the device due to excessive power supply voltage. However, with the configuration in Japanese Unexamined Patent Application Publication No. 9-8675, characteristics of the power amplifier circuit may be degraded due to the on resistance of the switch. In addition, with the configuration in Japanese Unexamined Patent Application Publication No. 9-8675, the size of the switch may be increased to increase the size of the power amplifier circuit.

In order to resolve the above problems, it is a possible benefit of the present disclosure to keep the characteristics of the power amplifier circuit with no influence on cost in the power amplifier circuit.

In order to resolve the above problems to achieve the possible benefit, a power amplifier circuit according to an aspect of the present disclosure includes amplifier units of multiple stages. The power amplifier circuit includes a first amplifier unit that amplifies a radio-frequency signal that is inputted, a second amplifier unit that amplifies an output from the first amplifier unit, and a switch portion provided on a power supply path to the first amplifier unit. Power is supplied to the first amplifier unit via the switch portion. The switch portion sets power supply to the first amplifier unit to ON or OFF. The power is directly supplied to the second amplifier unit not via the switch portion.

A power amplifier circuit according to another aspect of the present disclosure includes an amplifier unit of only one stage. The power amplifier circuit includes a first amplifier unit that amplifies a radio-frequency signal that is inputted, and a switch portion provided on a power supply path to the first amplifier unit. Power is supplied to the first amplifier unit via the switch portion. The switch portion sets power supply to the first amplifier unit to ON or OFF. The first amplifier unit includes an input terminal into which a signal to be amplified is inputted, a first FET having a gate to which the signal inputted into the input terminal is applied, a second FET connected between a power supply and reference potential with the first FET, an output terminal provided between the second FET and a load to output a signal that is amplified, and a resistor divider circuit for generating bias to be applied to a gate of the second FET. The first FET is cascode-connected to the second FET.

According to the present disclosure, it is possible to keep characteristics of the power amplifier circuit with no influence on cost.

### BRIEF DESCRIPTION OF THE SEVERAL VIEWS OF THE DRAWINGS

FIG. 1 is a diagram illustrating the configuration of a power amplifier circuit of a first comparative example.

FIG. 2 is a diagram illustrating the configuration of a power amplifier circuit of a second comparative example.

FIG. 3 is a diagram illustrating a power amplifier circuit according to a first embodiment.

FIG. 4 is a diagram illustrating an example of the configuration of a communication apparatus including a power amplifier circuit.

FIG. 5 is a diagram illustrating the configuration of an amplifier unit used in a power amplifier circuit of a third comparative example.

FIG. 6 is a diagram illustrating an example of a configuration in which a switch is connected to an amplifier unit.

FIG. 7 is a diagram illustrating an amplifier unit used in a power amplifier circuit of a fourth comparative example.

FIG. 8 is a diagram illustrating an amplifier unit used in a power amplifier circuit according to a second embodiment.

FIG. 9 is a graph describing the relationship between the respective voltage values.

FIG. 10 is a diagram illustrating an amplifier unit used in a power amplifier circuit according to a third embodiment.

FIG. 11 is a waveform diagram indicating an example of a signal resulting from inversion of an output signal from a comparator in FIG. 10.

FIG. 12 is a graph indicating input voltage and output voltage into and from a switch provided between a power supply and the amplifier unit.

FIG. 13 is a graph indicating the input voltage into the switch and gate bias.

FIG. 14 is a graph indicating an example of how the on resistance is varied.

FIG. 15 is a diagram illustrating an example of a switch using only PMOS.

FIG. 16 is a diagram illustrating an example of a switch using only NMOS.

FIG. 17 is a diagram illustrating an example of the switch using the PMOS and the NMOS.

FIG. 18 is a diagram illustrating an amplifier unit used in a power amplifier circuit according to a fourth embodiment.

FIG. 19 is a diagram describing hysteresis characteristics of the output signal from the comparator.

FIG. 20 is a diagram illustrating an example of the configuration of a variable resistor in FIG. 18.

FIG. 21 is a diagram illustrating the configuration of a power amplifier circuit according to a fifth embodiment.

FIG. 22 is a diagram illustrating an example of the configuration of a communication apparatus including the power amplifier circuit.

### DETAILED DESCRIPTION OF THE DISCLOSURE

Embodiments of the present disclosure will herein be described in detail with reference to the drawings. The same reference numerals and symbols are used in the following description of the respective embodiments to identify the same components or equivalent components and description of such components is simplified or omitted. The present disclosure is not limited by the respective embodiments. In addition, the components in the respective embodiments include components easily replaceable by the person skilled in the art or substantially the same components. The components described below can appropriately be combined. Furthermore, the components may be omitted, replaced, or modified without departing from the spirit and scope of the disclosure.

### First embodiment

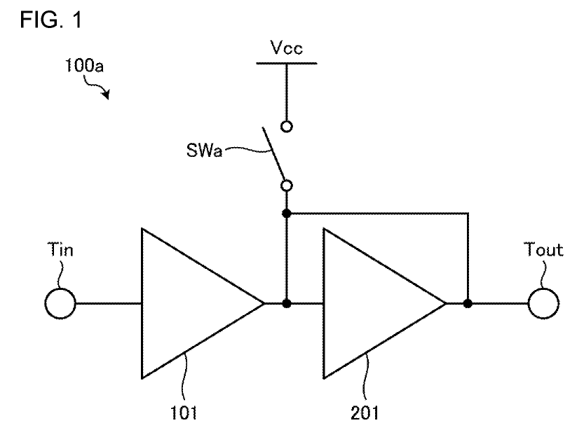

A first comparative example and a second comparative example will be described first in order to facilitate the understanding of a first embodiment. FIG. 1 is a diagram illustrating the configuration of a power amplifier circuit 100a of the first comparative example. Referring to FIG. 1, the power amplifier circuit 100a is a two-stage amplifier circuit and includes amplifier units 101 and 201. The first-stage (upstream stage) amplifier unit 101 is an amplifier unit at a driver stage. The amplifier unit 101 amplifies a signal inputted into an input terminal Tin and outputs the signal to the amplifier unit 201. The second-stage (downstream stage) amplifier unit 201 is an amplifier unit at a power stage. The amplifier unit 201 amplifies the signal outputted from the amplifier unit 101 and outputs the signal from an output terminal Tout.

The power amplifier circuit 100a has a switch SWa commonly provided for the amplifier units 101 and 201. In other words, the switch SWa corresponding to both of the amplifier units 101 and 201 is provided. Voltage of a power supply Vcc is supplied to the amplifier units 101 and 201 via the switch SWa. It is assumed that a transistor having an emitter that is grounded is provided for each of output portions of the amplifier units 101 and 201 of this example. Accordingly, the voltage of the power supply Vcc is applied to the output sides of the amplifier units 101 and 201.

The first comparative example illustrated in FIG. 1 operates in the following manner. In the power amplifier circuit 100a, when the switch SWa is set to an on state, the voltage of the power supply Vcc is supplied to the amplifier units 101 and 201. Upon supply of the voltage of the power supply Vcc, amplification operations by the amplifier units 101 and 201 are performed. When the switch SWa is set to an off state, the voltage of the power supply Vcc is not supplied to the amplifier units 101 and 201. At this time, the amplification operations by the amplifier units 101 and 201 are not performed.

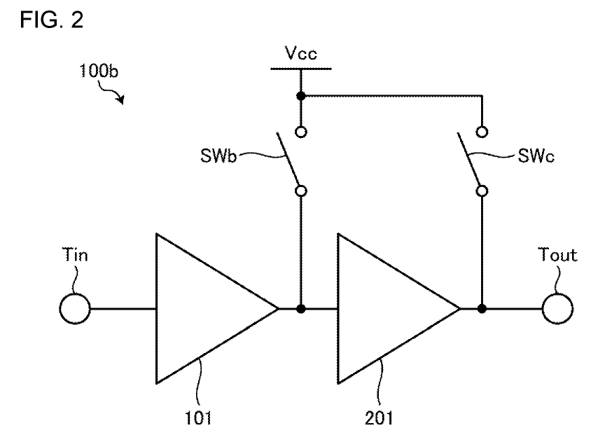

FIG. 2 is a diagram illustrating the configuration of a power amplifier circuit 100b of the second comparative example. Referring to FIG. 2, the power amplifier circuit 100b has a switch SWb provided for the amplifier unit 101 and a switch SWc provided for the amplifier unit 201, unlike the power amplifier circuit 100a. Voltage of the power supply Vcc is supplied to the amplifier unit 101 via the switch SWb. The voltage of the power supply Vcc is supplied to the amplifier unit 201 via the switch SWc.

The second comparative example illustrated in FIG. 2 operates in the following manner. In the power amplifier circuit 100b, when the switch SWb is set to the on state, the voltage of the power supply Vcc is supplied to the amplifier unit 101. Upon supply of the voltage of the power supply Vcc, the amplification operation by the amplifier unit 101 is performed. When the switch SWb is set to the off state, the voltage of the power supply Vcc is not supplied to the amplifier unit 101. At this time, the amplification operation by the amplifier unit 101 is not performed. When the switch SWc is set to the on state, the voltage of the power supply Vcc is supplied to the amplifier unit 201. Upon supply of the voltage of the power supply Vcc, the amplification operation by the amplifier unit 201 is performed. When the switch SWc is set to the off state, the voltage of the power supply Vcc is not supplied to the amplifier unit 201. At this time, the amplification operation by the amplifier unit 201 is not performed.

In setting of power supply to the amplifier of each stage to ON or OFF, the on resistance of the switch may have influence on characteristics of the power amplifier circuit. In particular, current flowing through the power-stage amplifier, which is the second-stage (downstream stage) amplifier, is larger than current flowing through the driver-stage amplifier, which is the first-stage (upstream stage) amplifier. Accordingly, the provision of the switch for the power-stage amplifier may greatly degrade amplification characteristics of the power-stage amplifier. In order to reduce the on resistance of the switch, it may be necessary to increase the size of the transistor composing the switch. Increasing the size of the transistor composing the switch undesirably increases the entire size of the device. For example, as for the switch SWa (refer to FIG. 1) and the switch SWc (refer to FIG. 2), the problem of necessity of increase of the sizes of the transistors occurs in order to reduce the on resistances of the transistors realizing the switches. Increasing the sizes of the transistors increases the size of the device, which undesirably has great influence on cost.

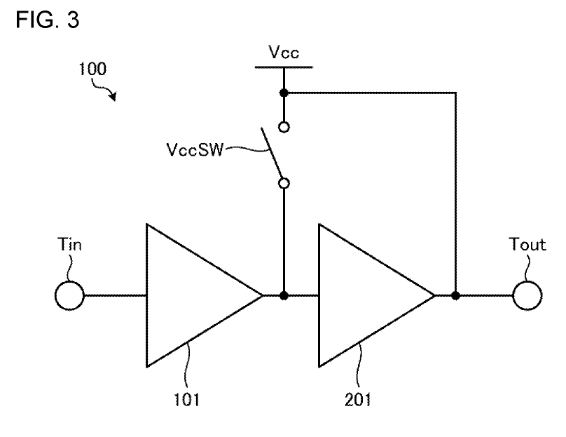

FIG. 3 is a diagram illustrating a power amplifier circuit 100 according to the first embodiment. The power amplifier circuit 100 includes the amplifier units 101 and 201 of multiple stages, as in the first comparative example and the second comparative example described above with reference to FIG. 1 and FIG. 2, respectively. The power amplifier circuit 100 has a switch VccSW. The switch VccSW is provided on a power supply path from the power supply Vcc to the amplifier unit 101. Power is supplied from the power supply Vcc to the amplifier unit 101 via the switch VccSW. The switch VccSW sets power supply from the power supply Vcc to the amplifier unit 101 to ON or OFF. The switch VccSW corresponds to a switch portion of the present disclosure. The amplifier unit 101 corresponds to a first amplifier unit of the present disclosure. Although the power amplifier circuit including the amplifier units of the two stages is described here, the number of the stages is not restricted as long as the number of the stages is two or more. The power amplifier circuit may include amplifier units of three or more stages.

The switch VccSW is controlled so as to be in the on state if the voltage of the power supply Vcc is lower than or equal to a predetermined threshold value. The switch VccSW is controlled so as to be in the off state if the voltage of the power supply Vcc exceeds the predetermined threshold value. The predetermined threshold value is, for example, a maximum driving voltage of the amplifier unit 101.

Power is directly supplied from the power supply Vcc to the amplifier unit 201 not via the switch VccSW. Accordingly, the switch corresponding to the amplifier unit 201 is not required. The sizes of the transistors are suppressed, compared with the first comparative example and the second comparative example. The amplifier unit 201 corresponds to a second amplifier unit of the present disclosure.

In the power amplifier circuit 100, when the switch VccSW is in the on state, the amplifier unit 101 amplifies the signal inputted into the input terminal Tin and outputs the signal to the amplifier unit 201, as in the first comparative example and the second comparative example. The amplifier unit 201 amplifies the output signal from the amplifier unit 101 and outputs the signal from the output terminal Tout.

The switch VccSW corresponding to the amplifier unit 101 is provided, no switch corresponding to the amplifier unit 201 is provided, and the switch VccSW is set to the on state if the voltage of the power supply Vcc is higher than or equal to the predetermined threshold value. Controlling the switch VccSW in the above manner enables the characteristics of the power amplifier circuit to be kept with no influence on the cost.

In the power amplifier circuit 100, the amplifier unit 101 may be formed on a silicon die and the amplifier unit 201 may be formed on a die other than the silicon die. The silicon die means a die made of Si and is, for example, a die using a Silicon-on-Insulator (SOI) substrate. The die other than the silicon die is, for example, a die made of GaAs. With such a configuration, also when the amplifier unit 101 is composed of multiple transistors stacked on the silicon die, as described below, it is possible to suppress the maximum voltage applied to the power amplifier circuit to prevent the degradation of the characteristics of the power amplifier circuit while ensuring breakdown voltage.

### Communication apparatus

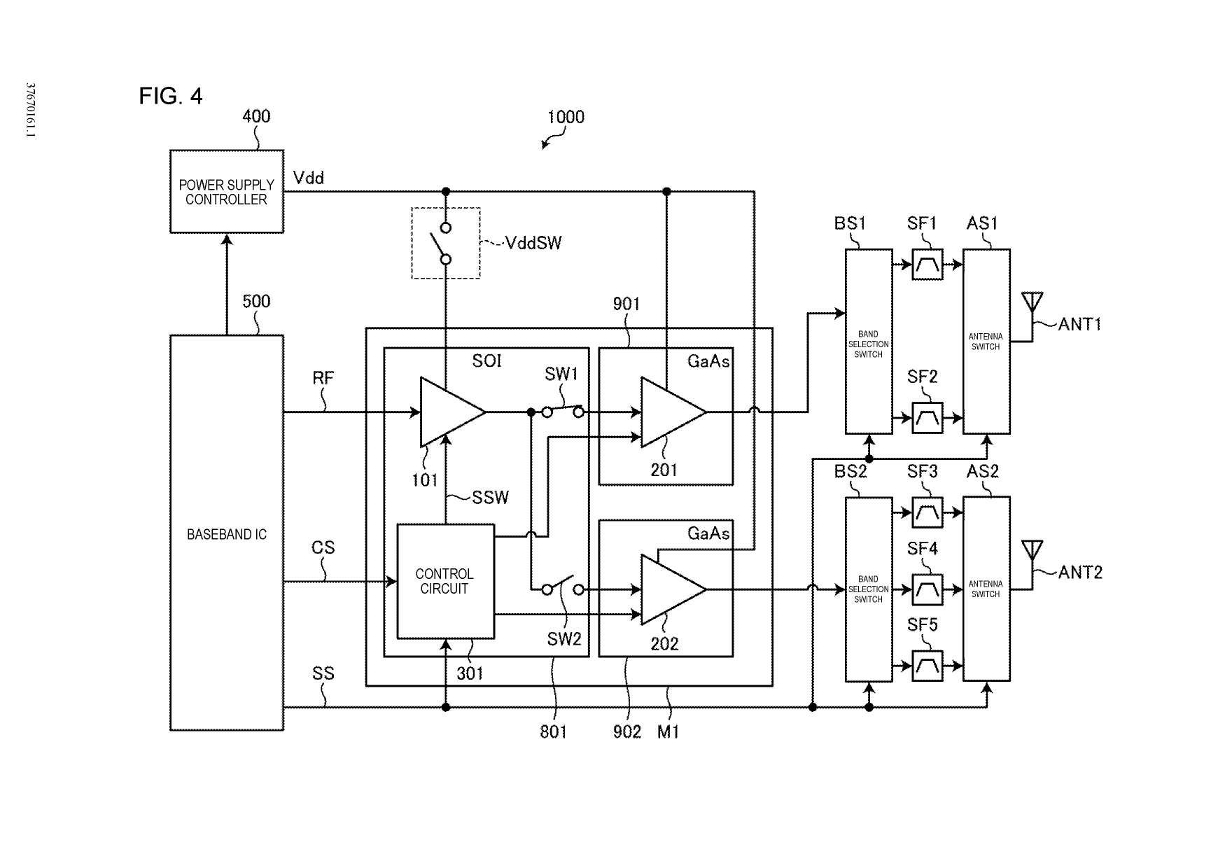

A communication apparatus including the power amplifier circuit will now be described. FIG. 4 is a diagram illustrating an example of the configuration of a communication apparatus including a power amplifier circuit. Referring to FIG. 4, a communication apparatus 1000 includes a power amplifier circuit M1, band selection switches BS1 and BS2, filters SF1 to SF5, antenna switches AS1 and AS2, antennas ANT1 and ANT2, a power supply controller 400, a baseband integrated circuit (IC) 500, and a switch VddSW. The switch VddSW corresponds to the switch portion of the present disclosure.

The power amplifier circuit M1 is a power amplifier (PA) module and has a function as a power amplifier circuit. The power amplifier circuit M1 includes the driver-stage amplifier unit 101, power-stage amplifier units 201 and 202, switches SW1 and SW2, and a control circuit 301.

An output end of the driver-stage amplifier unit 101 is outputted to an input end of the power-stage amplifier unit 201 via the switch SW1. The output end of the driver-stage amplifier unit 101 is outputted to an input end of the power-stage amplifier unit 202 via the switch SW2. The amplifier unit 101 is the amplifier unit at the upstream stage, that is, at the driver-stage. The amplifier units 201 and 202 are the amplifier units at the downstream stage, that is, at the power-stage.

The power-stage amplifier units 201 and 202 are each composed of, for example, a bipolar transistor. The control circuit 301 is a circuit that outputs a control signal for controlling the amplifier units 101 and 201. For example, the control circuit 301 supplies a gate bias control signal SSW to the amplifier unit 101. The control circuit 301 supplies bias current to the amplifier units 201 and 202. The amplifier unit 101 and the control circuit 301 are realized by, for example, a Silicon-on-Insulator (SOI) substrate 801. The amplifier units 201 and 202 are realized by, for example, GaAs substrates 901 and 902, respectively.

Here, the switch SW1 and the switch SW2 are controlled so that one is in the off state when the other is in the on state. Accordingly, one of the power-stage amplifier unit 201 and amplifier unit 202 is in a stand-by state in which the amplification operation is not performed when the other thereof is performing the amplification operation. In other words, the amplifier unit 201 and the amplifier unit 202 are alternatively in an operating state and are in the stand-by state when they are not in the operating state. The amplifier unit that is in an amplification operating state, among the amplifier unit 201 and the amplifier unit 202, operates in, for example, any of a high power mode (HPM), a middle power mode (MPM), and a low power mode (LPM).

The band selection switch BS1 is a switch that selects a frequency band based on a band selection control signal SS. The band selection switch BS2 is a switch that selects a frequency band based on the band selection control signal SS.

The filters SF1 to SF5 are, for example, surface acoustic wave (SAW) filters. The filters SF1 and SF2 each extract a signal of a required frequency band from an output from the band selection switch BS1. The filters SF3 to SF5 each extract a signal of a required frequency band from an output from the band selection switch BS2.

The antenna switch AS1 selects an output from the filter SF1 or an output from the filter SF2 based on the band selection control signal SS. The antenna switch AS2 selects an output from the filter SF3, an output from the filter SF4, or an output from the filter SF5 based on the band selection control signal SS. The antenna ANT1 emits the signal selected by the antenna switch AS1 as electromagnetic waves. The antenna ANT2 emits the signal selected by the antenna switch AS2 as the electromagnetic waves.

The power supply controller 400 is a power supply control module that outputs power supply Vdd. The power supply Vdd is inputted into the power amplifier circuit M1. The power supply controller 400 includes, for example, a direct current-direct current (DC-DC) converter that converts a direct-current voltage level. Although a reference symbol "Vcc" is used for the power supply because the bipolar transistor is assumed in the first embodiment described above, a reference symbol "Vdd" is used for the power supply because a field effect transistor (hereinafter referred to as an FET) is assumed in the following description.

The baseband IC 500 transmits a radio-frequency (RF) signal to the power amplifier circuit M1. In addition, the baseband IC 500 transmits a control signal CS or the band selection control signal SS to each component in the communication apparatus 1000 in accordance with the frequency band to be outputted. The baseband IC 500 transmits the band selection control signal SS to the band selection switches BS1 and BS2 and the antenna switches AS1 and AS2. The baseband IC 500 outputs a signal for controlling the power supply Vdd outputted from the power supply controller 400.

The switch VddSW is provided on the power supply path from the power supply Vdd to the amplifier unit 101. The power is supplied from the power supply Vdd to the amplifier unit 101 via the switch VddSW. The switch VddSW sets the power supply to the amplifier unit 101 to ON or OFF. The switch VddSW corresponds to the switch portion of the present disclosure.

### Operation

The baseband IC 500 controls each component in the communication apparatus 1000 so that the signal passes through a desired path to transmit the RF signal. The RF signal is inputted into the power amplifier circuit M1 and is amplified by the driver-stage amplifier unit 101. The RF signal amplified by the amplifier unit 101 is inputted into the power-stage amplifier unit 201 or 202 in accordance with the states of the switches SW1 and SW2. The signal that is inputted into the amplifier unit 201 to be amplified is outputted from the antenna ANT1 via the band selection switch BS1, the filter SF1 or SF2, and the antenna switch AS1. The signal that is inputted into the amplifier unit 202 to be amplified is outputted from the antenna ANT2 via the band selection switch BS2, any of the filters SF3 to SF5, and the antenna switch AS2.

The power supply controller 400 is controlled by the baseband IC 500. The voltage value of the power supply Vdd outputted from the power supply controller 400 is controlled in accordance with output power from the amplifier unit 201 or 202, which is in the operating state. Accordingly, the voltage value of the power supply Vdd is varied. For example, when average power tracking (APT) or envelope tracking (ET) is performed, the voltage value of the power supply Vdd is varied.

### Second embodiment

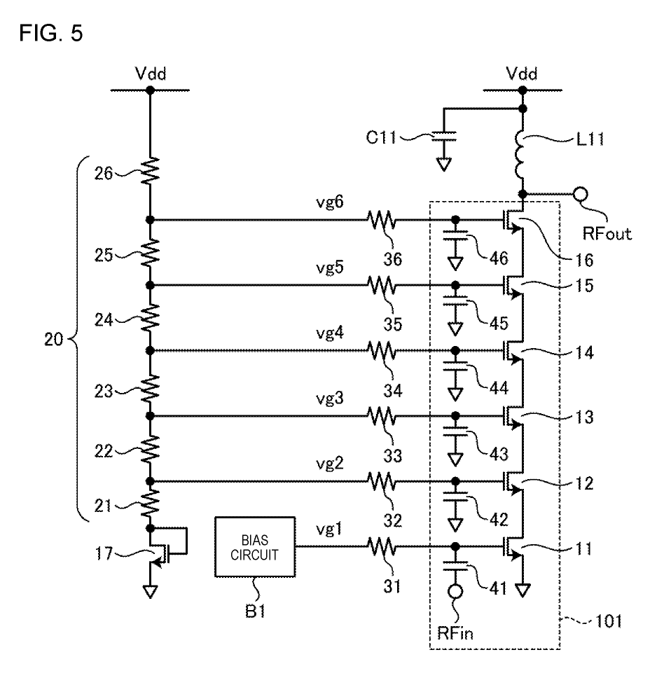

A third comparative example and a fourth comparative example will be described first in order to facilitate the understanding of a second embodiment. FIG. 5 is a diagram illustrating the configuration of an amplifier unit used in a power amplifier circuit of the third comparative example. FIG. 5 illustrates the configuration of the amplifier unit that does not include the switch VddSW described below. Referring to FIG. 5, the amplifier unit includes multiple field effect transistors, that is, FETs 11, 12, 13, 14, 15, and 16, resistors 21, 22, 23, 24, 25, and 26, resistors 31, 32, 33, 34, 35, and 36, capacitors 41, 42, 43, 44, 45, and 46, a FET 17, a choke coil L11, a bypass capacitor C11, and a bias circuit B1.

The FETs 11, 12, 13, 14, 15, and 16 are provided between reference potential and the power supply Vdd. The drain of the FETs 11, 12, 13, 14, 15, and 16 are cascode-connected to each other. Specifically, the drain of each FET is connected to the source of the adjacent FET. More specifically, the source of the FET 11 is connected to the reference potential and the drain of the FET 11 is connected to the source of the FET 12. The drain of the FET 12 is connected to the source of the FET 13. The drain of the FET 13 is connected to the source of the FET 14. The drain of the FET 14 is connected to the source of the FET 15. The drain of the FET 15 is connected to the source of the FET 16. The drain of the FET 16 is connected to the power supply Vdd via the choke coil L11. In this description, the FET 11 may be called a first FET and the FET 12 may be called a second FET. The reference potential is, for example, ground potential. The same applies to the following description.

Although the voltage value of the power supply Vdd is a fixed value, the voltage value of the power supply Vdd may be varied, as described below. An output terminal RFout is connected between the choke coil L11 and the FET 16. The output terminal RFout is connected to the downstream-stage amplifier unit. The output terminal RFout is connected to the power supply Vdd via the choke coil L11.

The resistor 31 and the capacitor 41 are provided for the FET 11. One end of the resistor 31 and one end of the capacitor 41 are connected to the gate of the FET 11. An input terminal RFin is connected to the other end of the capacitor 41. A signal to be amplified is inputted into the input terminal RFin.

The resistor 32 and the capacitor 42 are provided for the FET 12. One end of the resistor 32 and one end of the capacitor 42 are connected to the gate of the FET 12. The other end of the capacitor 42 is connected to the reference potential.

The resistor 33 and the capacitor 43 are provided for the FET 13. One end of the resistor 33 and one end of the capacitor 43 are connected to the gate of the FET 13. The other end of the capacitor 43 is connected to the reference potential.

The resistor 34 and the capacitor 44 are provided for the FET 14. One end of the resistor 34 and one end of the capacitor 44 are connected to the gate of the FET 14. The other end of the capacitor 44 is connected to the reference potential.

The resistor 35 and the capacitor 45 are provided for the FET 15. One end of the resistor 35 and one end of the capacitor 45 are connected to the gate of the FET 15. The other end of the capacitor 45 is connected to the reference potential.

The resistor 36 and the capacitor 46 are provided for the FET 16. One end of the resistor 36 and one end of the capacitor 46 are connected to the gate of the FET 16. The other end of the capacitor 46 is connected to the reference potential.

The drain of the FET 17 is connected to the gate of the FET 17. In other words, the FET 17 is a diode-connected transistor. The FET 17 is provided between the resistor 21 and the reference potential.

The resistors 21, 22, 23, 24, 25, and 26 are ladder resistors that are connected in series between the power supply Vdd and the reference potential. The resistors 21, 22, 23, 24, 25, and 26 compose a resistor divider circuit 20. The resistor divider circuit 20 divides the voltage difference between the power supply Vdd and the reference potential to generate bias to be applied to the gate of each of the FETs 12 to 16. Realizing the respective resistors 21, 22, 23, 24, 25, and 26 by the same ladder resistors prevents inversion of gate bias of each stage and so on due to shift of pairing of the resistors or the like. Here, the "same ladder resistors" mean ladder resistors having the same manufacturing process and the same material.

One end of the resistor 21 is connected to the drain and the gate of the FET 17. The one end of the resistor 21 is connected to the reference potential via the diode formed by the FET 17. The FET 17 is connected to the reference potential side of the resistor divider circuit 20. Accordingly, the FET 17 is provided between the resistor divider circuit 20 and the reference potential.

In the resistor divider circuit 20, the resistor 21 is connected in series to the resistor 22. The node between the resistor 21 and the resistor 22 is connected to the other end of the resistor 32. The voltage at the node between the resistor 21 and the resistor 22 is applied to the gate of the FET 12 as bias vg2. The resistor 22 is connected in series to the resistor 23. The node between the resistor 22 and the resistor 23 is connected to the other end of the resistor 33. The voltage at the node between the resistor 22 and the resistor 23 is applied to the gate of the FET 13 as bias vg3. The resistor 23 is connected in series to the resistor 24. The node between the resistor 23 and the resistor 24 is connected to the other end of the resistor 34. The voltage at the node between the resistor 23 and the resistor 24 is applied to the gate of the FET 14 as bias vg4. The resistor 24 is connected in series to the resistor 25. The node between the resistor 24 and the resistor 25 is connected to the other end of the resistor 35. The voltage at the node between the resistor 24 and the resistor 25 is applied to the gate of the FET 15 as bias vg5. The resistor 25 is connected in series to the resistor 26. The node between the resistor 25 and the resistor 26 is connected to the other end of the resistor 36. The voltage at the node between the resistor 25 and the resistor 26 is applied to the gate of the FET 16 as bias vg6. The other end of the resistor 31 is connected to the bias circuit B1. Bias vg1 outputted from the bias circuit B1 is applied to the gate of the FET 11 via the resistor 31.

The choke coil L11 is connected in series between the power supply voltage Vdd and the amplifier unit 101. One end of the bypass capacitor C11 is connected to the node between one end of the choke coil L11 and the power supply voltage Vdd. The other end of the bypass capacitor C11 is connected to the reference potential.

The amplifier unit 101 illustrated in FIG. 5 operates in the following manner. Specifically, the bias (that is, the gate bias) generated by the resistance voltage division by the resistor divider circuit 20 is applied to the gate of each of the FET 12 to the FET 16. The amplifier unit 101 amplifies the radio-frequency signal inputted into the input terminal RFin. The amplifier unit 101 outputs the amplified signal from the output terminal RFout.

In this example, the FET 11 to the FET 16 are provided and the six FETs are cascode-connected to each other. The number of FETs that are cascode-connected (hereinafter referred to as the number of stacks) is determined so as to ensure the breakdown voltage at the maximum voltage applied by the power supply Vdd. In the other words, the number of stacks is determined so as not to cause breakdown even if the maximum voltage is applied. The maximum voltage described above may be hereinafter referred to as absolute maximum ratings (AMR) voltage.

However, if the difference lies between an operating range of the power supply Vdd, in which the characteristics of the power amplifier circuit are required to be ensured, and the AMR voltage, it may be necessary to provide the number of stacks larger than the number of stacks required for the power supply Vdd within the operating range to ensure the breakdown voltage against the AMR voltage. Increasing the number of stacks increases the on resistance due to the FET close to the power supply Vdd to cause the degradation of the characteristics of the power amplifier circuit. For example, when it is sufficient to set the number of stacks to "four" only to ensure the breakdown voltage against the operating range of the power supply Vdd, it may be necessary to increase the number of stacks in order to ensure the breakdown voltage against the AMR voltage to set the number of stacks to "six". In this case, the two FETs: the FETs 15 and 16 close to the power supply Vdd appear as the on resistance within the operating range to cause the degradation of the characteristics of the power amplifier circuit.

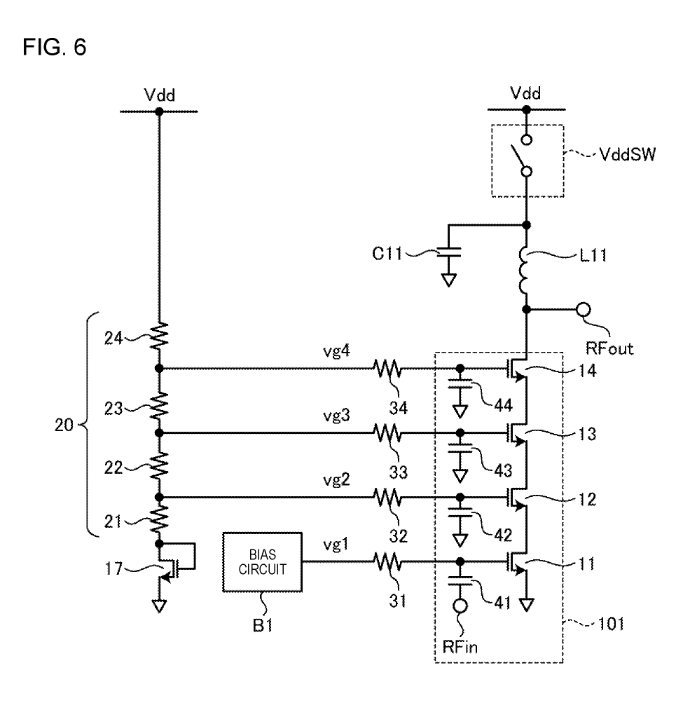

FIG. 6 is a diagram illustrating an example of a configuration in which the switch VddSW is connected to the amplifier unit. Referring to FIG. 6, the switch VddSW is provided between wiring of the power supply Vdd and the choke coil L11. The number of stacks of the amplifier unit 101 is "four".

The switch VddSW is set to the off state when the voltage value of the power supply Vdd exceeds the operating range. This enables the maximum voltage of the power supply Vdd to be applied to the power amplifier circuit to be suppressed to a value within the operating range or a value slightly exceeding the operating range. With such a configuration, it is possible to suppress the maximum voltage to be applied to the power amplifier circuit to decrease the number of stacks of the power amplifier circuit while ensuring the breakdown voltage. Since the number of stacks can be decreased, it is possible to prevent the degradation of the characteristics of the power amplifier circuit. The operating range is the voltage range used to drive the amplifier unit 101 and means a voltage range lower than or equal to the maximum driving voltage of the amplifier unit 101. In other words, a time when the voltage value of the power supply Vdd exceeds the operating range has the same meaning as a time when the voltage value of the power supply Vdd exceeds the maximum driving voltage of the amplifier unit 101.

Since the switch VddSW is provided between the power supply Vdd and the choke coil L11, the on resistance of the switch VddSW appears in terms of direct-current. However, the switch VddSW is grounded by the bypass capacitor C11, it is possible to cause the on resistance of the switch VddSW to disappear in terms of the radio-frequency.

If the switch VddSW is completely set to the off state when the voltage value of the power supply Vdd exceeds the operating range, the voltage of the power supply Vdd is applied only to the switch VddSW. If no FET adaptable to the AMR voltage of the power supply Vdd is prepared in a semiconductor process to manufacture the power amplifier circuit, it may be necessary to increase the number of stacks that are cascode-connected at the switch VddSW for the breakdown voltage.

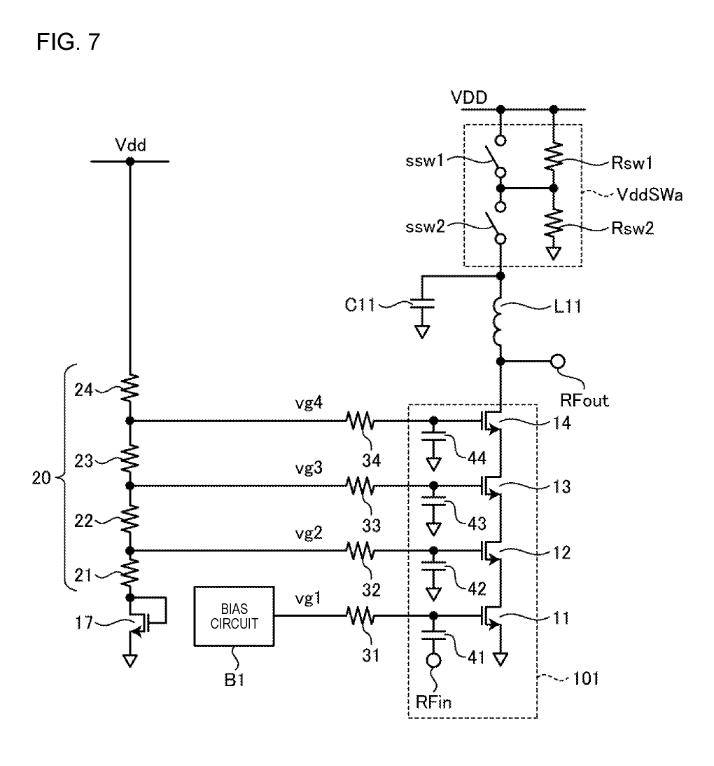

FIG. 7 is a diagram illustrating an amplifier unit used in a power amplifier circuit of the fourth comparative example. FIG. 7 illustrates a configuration in which a switch VddSWa for the breakdown voltage is connected to the amplifier unit 101. Referring to FIG. 7, the switch VddSWa includes switches SSW1 and SSW2 and resistors Rsw1 and Rsw2.

Each of the switches SSW1 and SSW2 is realized by, for example, a FET. One end of the switch SSW1 is connected to the wiring of the power supply Vdd. The other end of the switch SSW1 is connected to one end of the switch SSW2. The other end of the switch SSW2 is connected to the drain of the FET 14 via the choke coil L11. The choke coil L11 is connected in series between the switch VddSWa and the amplifier unit 101.

One end of the resistor Rsw1 is connected to the wiring of the power supply Vdd. The other end of the resistor Rsw1 is connected to one end of the resistor Rsw2. The other end of the resistor Rsw2 is connected to the reference potential. The voltage divided by the resistors Rsw1 and Rsw2 is applied to the node between the switch SSW1 and the switch SSW2.

As illustrated in FIG. 7, although cascode-connecting the switches SSW1 and the SSW2 using the FETs enables the applied voltage to be dispersed to each FET, the on resistance of the FETs has a value that is several times larger than the number of stacks. In addition, the area of the FETs has a magnitude that is several times larger than the number of stacks. In order to set the on resistance to a value corresponding to the on resistance of one FET, the area of the FETs has a magnitude that is square of the number of stacks. The influence of the on resistance of the switch VddSWa can be reduced in terms of the radio-frequency. However, since voltage drop occurs due to direct current of the amplifier unit 101, the higher on resistance of the switch VddSWa disadvantageously reduces the voltage applied to the operating amplifier unit 101.

Furthermore, if the switch VddSWa is completely set to the off state when the voltage value of the power supply Vdd exceeds the operating range, the voltage of the power supply Vdd is applied only to the switch VddSWa. Accordingly, the breakdown voltage higher than or equal to the AMR voltage is required for the switches SSW1 and SSW2 using the FETs, which are used in the switch VddSWa.

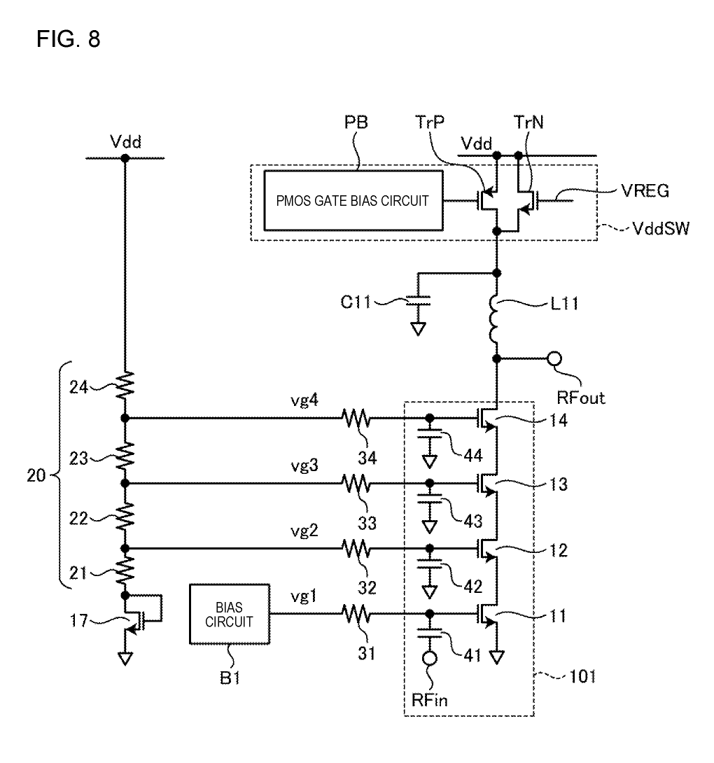

FIG. 8 is a diagram illustrating an amplifier unit used in a power amplifier circuit according to the second embodiment. In order to resolve the problems occurring in the fourth comparative example, in the second embodiment, a switch using a P-type metal oxide semiconductor field effect transistor (MOSFET) (hereinafter referred to as a PMOS switch) TrP is combined with a switch using an N-type MOSFET (hereinafter referred to as an NMOS switch) TrN to use the PMOS switch TrP and the NMOS switch TrN as a transfer gate. The source of the PMOS switch TrP is connected to the power supply Vdd. The drain of the NMOS switch TrN is connected to the power supply Vdd. The drain of the PMOS switch TrP is connected to the source of the NMOS switch TrN, and the power is supplied from the node between the drain of the PMOS switch TrP and the source of the NMOS switch TrN to the amplifier unit 101. The PMOS switch TrP corresponds to a PMOS transistor of the present disclosure. The NMOS switch TrN corresponds to an NMOS transistor of the present disclosure.

The switch VddSW includes a PMOS gate bias circuit PB. The PMOS gate bias circuit PB applies the bias to the gate of the PMOS switch TrP. The PMOS gate bias circuit PB applies to the bias, which sets the PMOS switch TrP to the off state if the voltage of the power supply Vdd is higher than or equal to a predetermined threshold value and sets the PMOS switch TrP to the on state if the voltage of the power supply Vdd is lower than the predetermined threshold value, to the gate of the PMOS switch TrP.

The PMOS switch TrP is set to the off state if the voltage of the power supply Vdd is higher than or equal to the predetermined threshold value and is set to the on state if the voltage of the power supply Vdd is lower than the predetermined threshold value. If the switch VddSW is completely set to the off state, it may be necessary to ensure the breakdown voltage against the AMR voltage only with the switch VddSW. In contrast, also when the voltage of the power supply Vdd is made higher and the switch VddSW is set to the off state, the voltage that is within the operating range and that is lower than or equal to the voltage value of the power supply Vdd is applied to the amplifier unit 101. This causes the voltage of the power supply Vdd to be divided with both the switch VddSW and the amplifier unit 101 to ensure the breakdown voltage of each of the switch VddSW and the amplifier unit 101.

Specifically, voltage about half of the AMR voltage (hereinafter referred to as voltage VREG) is continuously applied to the gate of the NMOS switch TrN also when the PMOS switch TrP is set to the off state to cause a source follower operation. As a result, as much as voltage resulting from subtraction of a threshold voltage value of the NMOS switch TrN from the voltage VREG is applied to the amplifier unit 101 to divide the voltage of the power supply Vdd. The voltage VREG can be generated in the power amplifier circuit.

Although the voltage is continuously applied to the top of the amplifier unit 101, that is, the drain of the FET 14, the amplifier unit 101 is concurrently set to the off state when the switch VddSW is set to the off state. Specifically, the bias vg1 from the bias circuit B1 is set to 0 [V] to set the FET 11 to OFF. As a result, the amplifier unit 101 does not amplify the RF signal and the RF signal is not outputted from the output terminal RFout. This enables the measures against breakdown of the amplifier unit 201 or 202 (refer to FIG. 4) downstream of the amplifier unit 101 to be realized.

### Relationship between respective voltage values

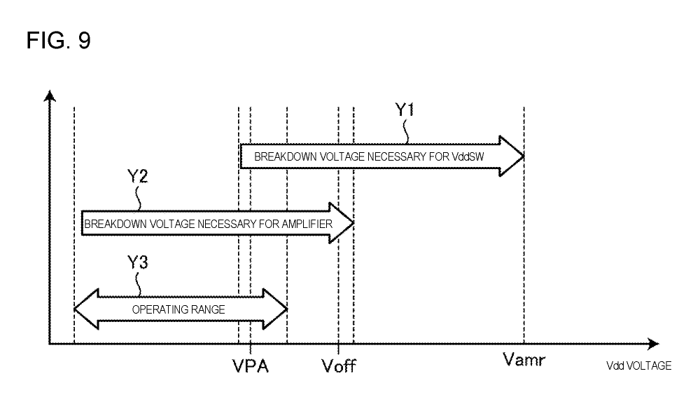

FIG. 9 is a graph describing the relationship between the respective voltage values. FIG. 9 indicates voltage at the top of the amplifier unit 101 (the output voltage from the switch VddSW) VPA after the switch VddSW is set to the off state, voltage Voff causing the switch VddSW to be in the off state, and AMR voltage Vamr.

Referring to FIG. 9, an arrow Y1 indicates the breakdown voltage which may be necessary for the switch VddSW. An arrow Y2 indicates the breakdown voltage which may be necessary for the amplifier unit 101. A double-headed arrow Y3 indicates the voltage within the operating range.

As illustrated in FIG. 9, the voltage Voff causing the switch VddSW to be in the off state is set between the AMR voltage Vamr and the maximum voltage of the operating range. It may be necessary for the breakdown voltage of the amplifier unit 101 to be designed so as to be higher than the voltage Voff causing the switch VddSW to be in the off state. In other words, the maximum voltage value of the operating range < the voltage Voff causing the switch VddSW to be in the off state < the breakdown voltage of the amplifier unit 101 < the AMR voltage.

In addition, it may be necessary to set the voltage VPA at the top of the amplifier unit 101 after the switch VddSW is set to the off state to a value lower than or equal to the voltage Voff causing the switch VddSW to be in the off state. In other words, the voltage value at the top of the amplifier unit 101 when the switch VddSW is in the off state ≤ the voltage Voff causing the switch VddSW to be in the off state.

Furthermore, it may be necessary to set the breakdown voltage of the switch VddSW to a value higher than the voltage, which is the difference between the AMR voltage Vamr and the voltage VPA at the top of the amplifier unit 101 after the switch VddSW is set to the off state. In other words, (the AMR voltage Vamr - the voltage VPA at the top of the amplifier unit 101 when the switch VddSW is in the off state) < the breakdown voltage of the amplifier unit 101.

### Third embodiment

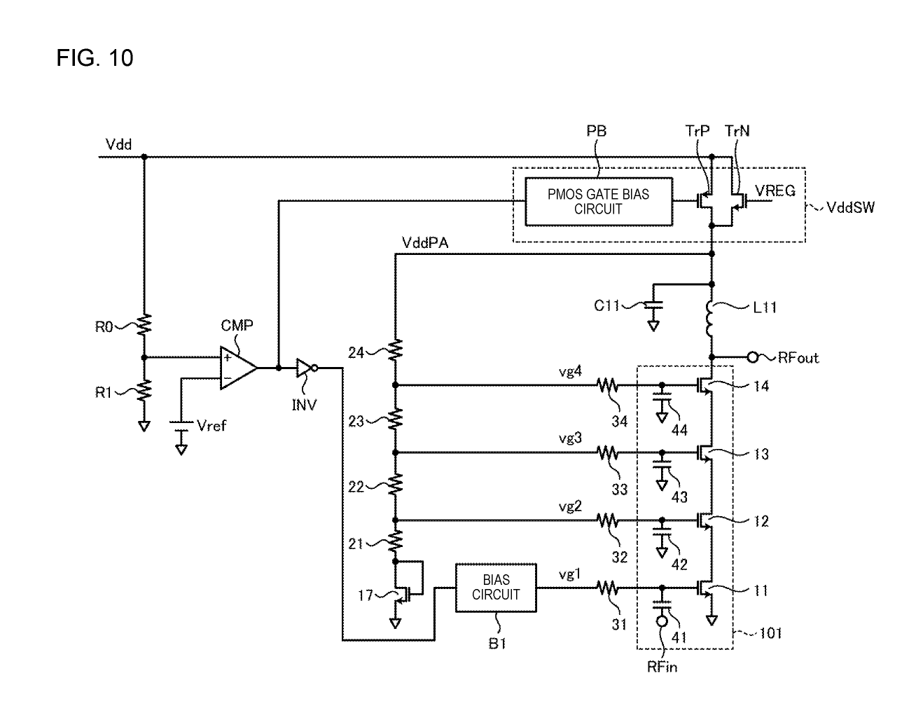

FIG. 10 is a diagram illustrating an amplifier unit used in a power amplifier circuit according to a third embodiment. A configuration in the third embodiment results from addition of a comparator CMP, resistors R0 and R1, an inverter INV, and a reference voltage source Vref to the configuration of the second embodiment.

The voltage between the power supply Vdd and the reference potential is divided by the resistors R0 and R1 to supply the divided voltage to a non-inverting input terminal (+ side) of the comparator CMP. Reference voltage of the reference voltage source Vref is inputted into an inverting input terminal (- side) of the comparator CMP. The comparator CMP compares the voltage of the power supply Vdd with the reference voltage of the reference voltage source Vref. The reference voltage of the reference voltage source Vref can be generated in the power amplifier circuit.

If the divided voltage of the power supply Vdd, which is divided by the resistors R0 and R1, exceeds the reference voltage of the reference voltage source Vref, an output signal from the comparator CMP is switched from a Low level to a High level. The PMOS switch TrP is controlled so as to be in the off state by switching the output signal from the comparator CMP from the Low level to the High level. It may be necessary to set a threshold value of the comparator CMP with respect to the reference voltage source Vref to a value that is higher than the operating range of the power supply Vdd and that is lower than or equal to the breakdown voltage of the amplifier unit 101.

The output signal from the comparator CMP is inverted by the inverter INV to be inputted into the bias circuit B1. This switches the bias vg1 from the bias circuit B1 to the amplifier unit 101 from the High level to the Low level. As a result, the amplifier unit 101 does not output the RF signal to prevent the breakdown of the downstream amplifier unit 201 or 202.

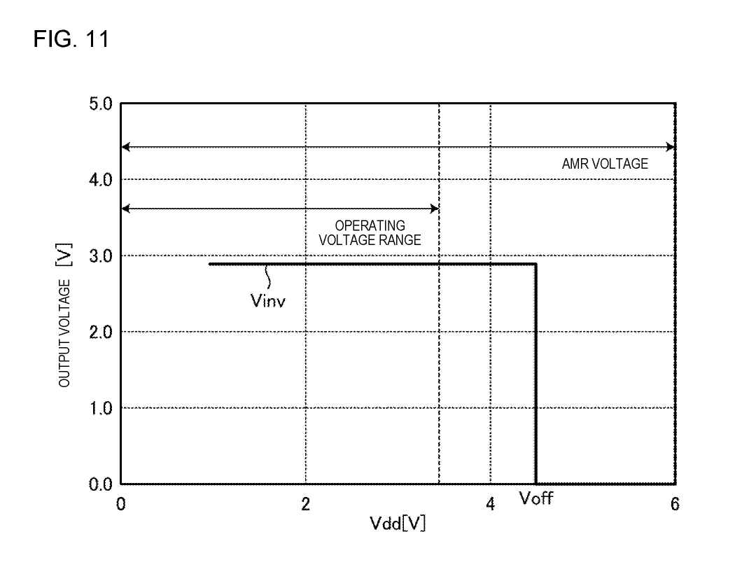

FIG. 11 is a waveform diagram indicating an example of a signal resulting from inversion of the output signal from the comparator CMP in FIG. 10. In other words, FIG. 11 is a waveform diagram indicating an example of an output signal from the inverter INV in FIG. 10. As indicated in FIG. 11, output voltage Vinv from the inverter INV is varied from the High level to the Low level at the voltage Voff that exceeds an operating voltage range of the power supply Vdd, which is used in a normal operation, to some extent and that is lower than the AMR voltage. The variation of the output voltage Vinv from the inverter INV in the above manner switches the bias vg1 from the bias circuit B1 to the amplifier unit 101 from the High level to the Low level. As a result, the amplifier unit 101 does not output the RF signal to prevent the breakdown of the downstream amplifier unit 201 or 202.

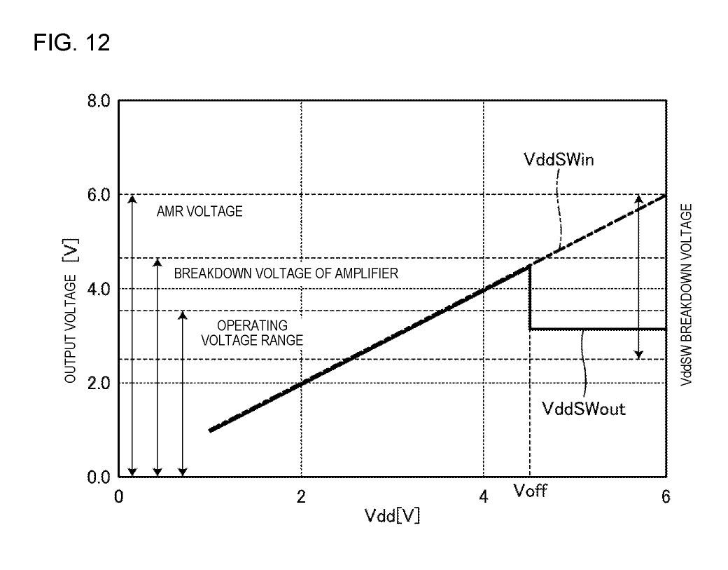

FIG. 12 is a graph indicating input voltage and output voltage into and from the switch VddSW, which is provided between the power supply Vdd and the amplifier unit 101. A sold line in FIG. 12 indicates output voltage VddSWout into the switch VddSW. An alternate long and short dash line in FIG. 12 indicates input voltage VddSWin from the switch VddSW.

As indicated in FIG. 12, the input voltage VddSWin into the switch VddSW is increased within the range of the AMR voltage. In contrast, although the output voltage VddSWout from the switch VddSW is increased in accordance with the input voltage VddSWin, the output voltage VddSWout is decreased at the voltage Voff, which exceeds the operating voltage range of the amplifier unit 101 to some extent and which is lower than the voltage value corresponding to the breakdown voltage of the amplifier unit 101. This is because the gate bias from the PMOS gate bias circuit PB is decreased to set the switch TrP to the off state. Even in the state in which the switch TrP is in the off state, the switch TrN is in the on state. At this time, the output voltage VddSWout has a voltage level close to the voltage VREG, which is the gate bias of the switch TrN.

If the switch VddSW is not provided, it may be necessary to design the breakdown voltage (the number of stacks) of the amplifier unit 101 in accordance with the AMR voltage. In contrast, when the switch VddSW is adopted, the voltage higher than or equal to the voltage value of the power supply Vdd causing the switch VddSW to be in the off state is not applied to the amplifier unit 101. Accordingly, it is possible to design the number of stacks of the amplifier unit 101 at the voltage lower than the AMR voltage to decrease the number of stacks. Decreasing the number of stacks improves the characteristics of the amplifier unit 101 within the operating voltage range.

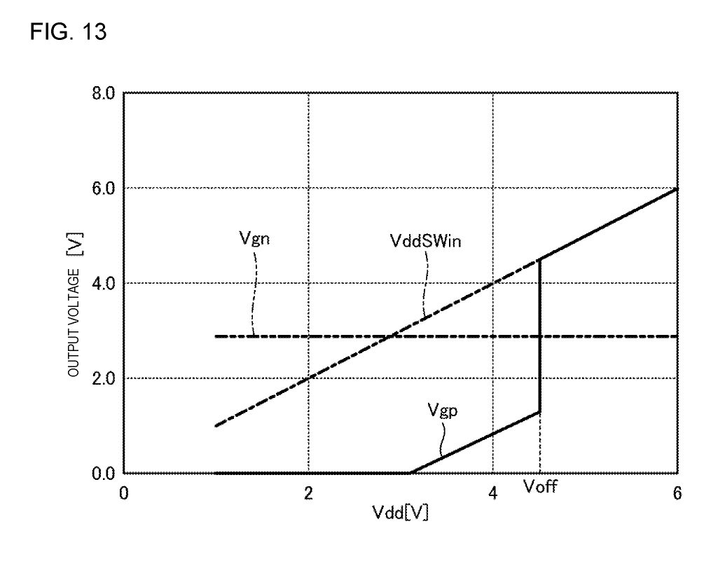

FIG. 13 is a graph indicating the input voltage into the switch VddSW and the gate bias. FIG. 13 indicates the input voltage VddSWin into the switch VddSW, gate bias Vgp to the switch TrP, and gate bias Vgn to the switch TrN. While the switch VddSW is in the on state, the gate bias Vgp to the switch TrP is controlled so as not to exceed element breakdown voltage of the source-gate voltage of the switch TrP due to the increase in voltage of the power supply Vdd. After the switch VddSW is set to the off state, the gate bias Vgp is made equal to the voltage of the power supply Vdd to set the switch TrP to the off state.

As for the switch TrN, the voltage VREG is continuously applied to the switch TrN as the gate bias Vgn regardless of whether the switch VddSW is in the on state or the off state. This controls the output voltage from the switch VddSW so as to be constant also after the switch TrP is in the off state. For example, the output voltage from the switch VddSW is controlled so as to be about 3 V to also ensure the breakdown voltage of the switch VddSW. In other words, the gate bias Vgn at which source voltage of the switch TrN is lower than a predetermined threshold value (for example, lower than voltage half of the AMR voltage illustrated in FIG. 12) when the switch TrP is in the off state is applied to the switch TrN regardless of the voltage value of the power supply Vdd. This causes the switch TrN to perform the source follower operation to keep the source voltage of the switch TrN so as not to exceed the breakdown voltage of the power amplifier circuit. In other words, the source follower operation is caused by continuously applying the voltage VREG to the gate of the NMOS switch TrN also when the PMOS switch TrP is in the off state.

The voltage value of the power supply Vdd may be controlled. For example, in the APT control, the voltage value of the power supply Vdd is controlled in accordance with the output power. In this case, the voltage value of the power supply Vdd is varied within a wide range from a higher value to a lower value.

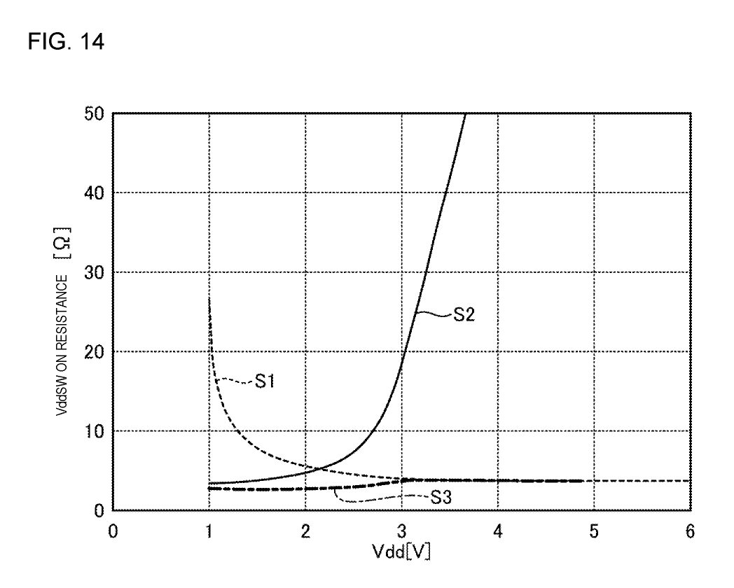

FIG. 14 is a graph indicating an example of how the on resistance is varied. FIG. 14 indicates a change curve S1 (a broken line in FIG. 14) of the on resistance of the PMOS switch TrP, a change curve S2 (a solid line in FIG. 14) of the on resistance of the NMOS switch TrN, and a change curve S3 (an alternate long and short dash line in FIG. 14) of the on resistance of the PMOS switch and the NMOS switch. FIG. 14 indicates the on resistances calculated when the switch VddSW is not in the off state.

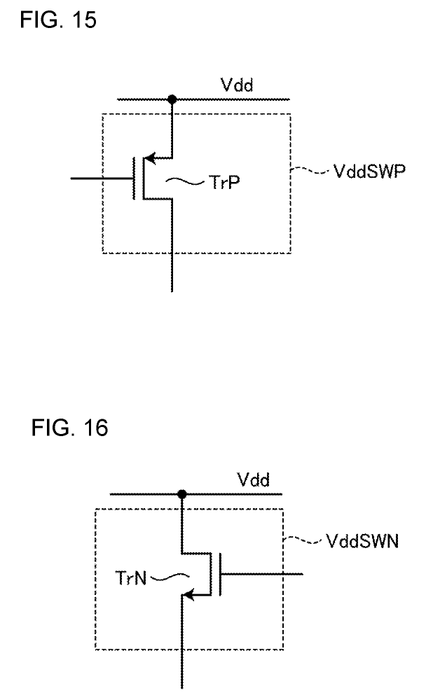

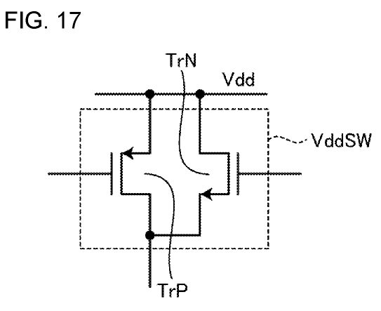

FIG. 15 is a diagram illustrating an example of a switch VddSWP using only the PMOS. The switch VddSWP in FIG. 15 includes the PMOS switch TrP. FIG. 16 is a diagram illustrating an example of a switch VddSWN using only the NMOS. The switch VddSWN in FIG. 16 includes the NMOS switch TrN. FIG. 17 is a diagram illustrating an example of the switch VddSW using the PMOS and the NMOS.

Referring back to FIG. 14, in the case of the switch VddSWP including only the PMOS switch TrP (refer to FIG. 15), gate-source voltage Vgs of the switch VddSWP is decreased with the decreasing voltage of the power supply Vdd to increase the on resistance. In the case of the switch VddSWN including only the NMOS switch TrN (refer to FIG. 16), since the gate bias is the voltage VREG, the gate-source voltage Vgs of the switch VddSWN is not ensured with the increasing voltage of the power supply Vdd to increase the on resistance. Since the gate-source voltage Vgs is increased, unlike the PMOS switch TrP, when the voltage of the power supply Vdd is decreased, the on resistance is decreased.

In the second embodiment and the third embodiment described above, the configuration in which the switch TrP is combined with the switch TrN is adopted (refer to FIG. 17). This enables the increase in the on resistance of the switch VddSW to be suppressed in the entire operating range of the power supply Vdd.

### Fourth embodiment

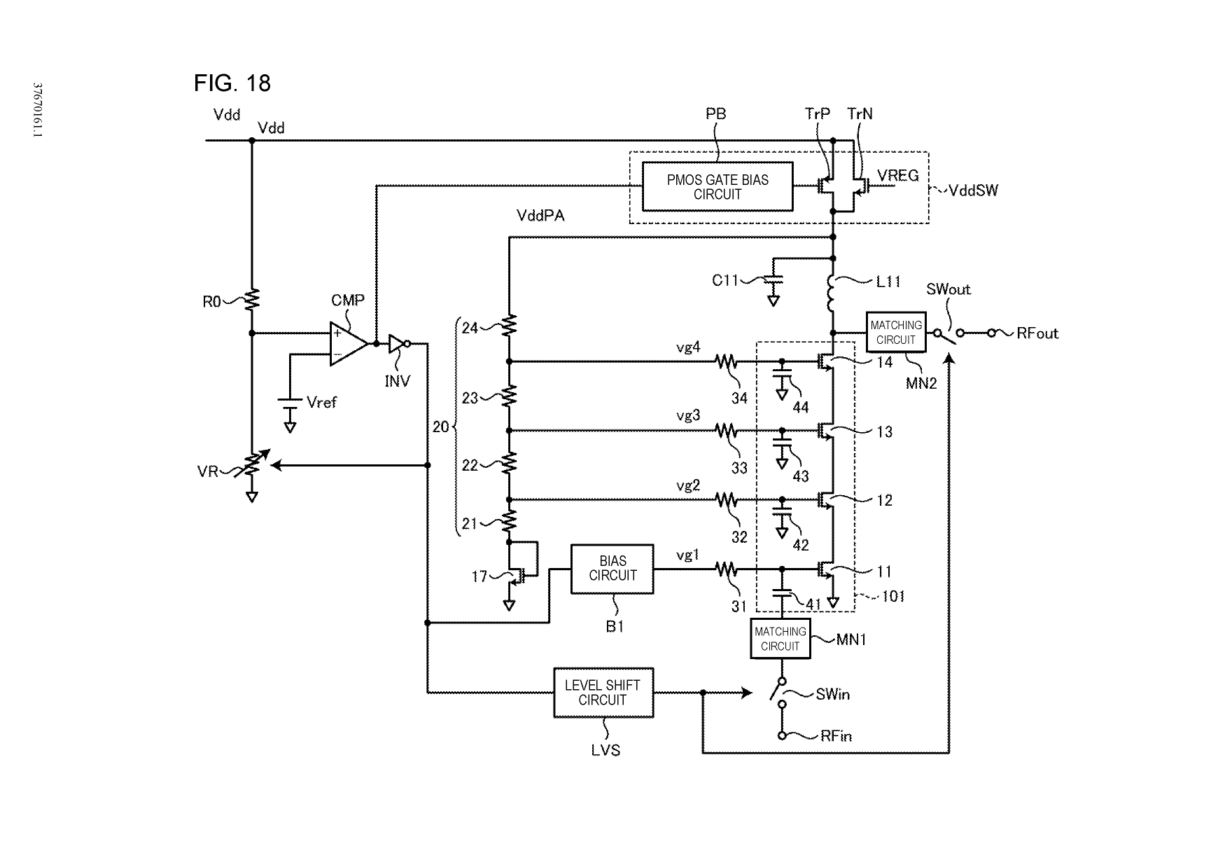

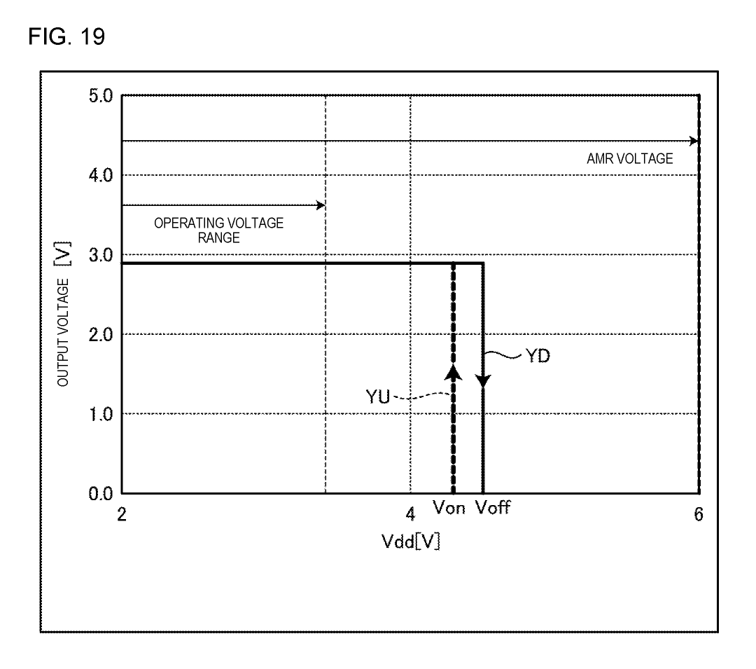

FIG. 18 is a diagram illustrating an amplifier unit used in a power amplifier circuit according to a fourth embodiment. In the fourth embodiment, a variable resistor VR is adopted, instead of the resistor R1 in the configuration of the third embodiment. The output signal from the comparator CMP may repeat a high-level (High-level) voltage and a low-level (Low-level) voltage near a threshold value. The repetition of the high-level voltage and the low-level voltage may cause the switch VddSW to repeat the on state and the off state.

Accordingly, in the present embodiment, hysteresis characteristics are given to the output signal from the comparator CMP to prevent the above repetition. Specifically, the resistance value of the variable resistor VR is controlled using the output from the inverter INV to give the hysteresis characteristics to the output signal from the comparator CMP.

FIG. 19 is a diagram describing the hysteresis characteristics of the output signal from the comparator CMP. When the power supply Vdd has the voltage Voff, the output signal from the comparator CMP makes a transition from the high level to the low level (an arrow YD in FIG. 19). In contrast, when the power supply Vdd has voltage Von, the output signal from the comparator CMP makes a transition from the low level to the high level (an arrow YU in FIG. 19). In other words, the output signal from the comparator CMP is the high-level voltage or the low-level voltage and the hysteresis characteristics are given for the transition from the high level to the low level (the arrow YD in FIG. 19) and the transition from the low level to the high level (the arrow YU in FIG. 19).

Referring back to FIG. 18, in the present embodiment, a switch SWin and a matching circuit MN1 are provided between the input terminal RFin and the amplifier unit 101. In addition, a matching circuit MN2 and a switch SWout are provided between the amplifier unit 101 and the output terminal RFout. Furthermore, a level shift circuit LVS that converts the level of the output signal from the inverter INV is provided.

The level of the output signal from the inverter INV may be converted by the level shift circuit LVS, and the switch SWin and the switch SWout may be controlled using an output signal from the level shift circuit LVS. The switch SWin and the switch SWout may be set to the off state at the timing when the switch TrP of the switch VddSW is set to the off state using the output signal from the comparator CMP to set the amplifier unit 101 to the off state.

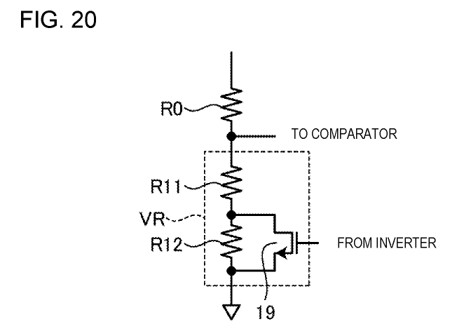

FIG. 20 is a diagram illustrating an example of the configuration of the variable resistor VR in FIG. 18. Referring to FIG. 20, the variable resistor VR includes a resistor R11, a resistor R12, and an FET 19. One end of the resistor R11 is connected to the resistor R0. The other end of the resistor R11 is connected to one end of the resistor R12. The other end of the resistor 12 is connected to the reference potential. The drain of the FET 19 is connected to the one end of the resistor R12. The source of the FET 19 is connected to the other end of the resistor R12. The output signal from the inverter INV (refer to FIG. 18) is applied to the gate of the FET 19.

When the output signal from the inverter INV has the high level, the FET 19 is in the on state. When the output signal from the inverter INV has the low level, the FET 19 is in the off state. Accordingly, the voltage to be inputted into the comparator CMP is varied between when the output signal from the inverter INV has the high level and when the output signal from the inverter INV has the low level. Consequently, as described above with reference to FIG. 19, it is possible to give the hysteresis characteristics for the transition from the high level to the low level of the output signal from the comparator CMP (the arrow YD in FIG. 19) and the transition from the low level to the high level of the output signal from the comparator CMP (the arrow YU in FIG. 19). Giving the hysteresis characteristics enables the repetition of the high-level voltage and the low-level voltage to be prevented near the threshold value.

### Fifth embodiment

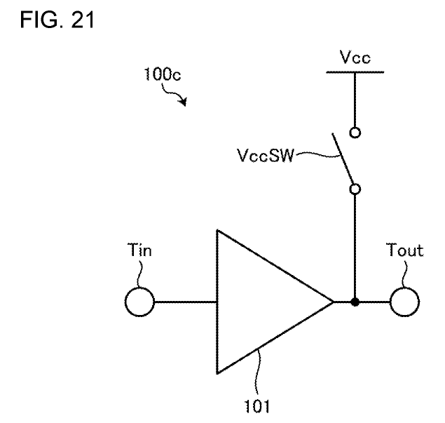

FIG. 21 is a diagram illustrating the configuration of a power amplifier circuit 100c according to a fifth embodiment. Referring to FIG. 21, the power amplifier circuit 100c differs from the power amplifier circuit 100 described above with reference to FIG. 3 and includes the amplifier unit 101 of only one stage. Specifically, the power amplifier circuit 100c includes the amplifier unit 101, which is the one-stage amplifier, and the switch VccSW provided for the amplifier unit 101. The voltage of the power supply Vcc is supplied to the amplifier unit 101 via the switch VccSW. The switch VccSW corresponds to the switch portion of the present disclosure. The amplifier unit 101 corresponds to the first amplifier unit of the present disclosure. It is assumed that a transistor having an emitter that is grounded is provided in an output portion of the amplifier unit 101 of this example. Accordingly, the voltage of the power supply Vcc is applied to the output side of the amplifier unit 101.

The switch VccSW is controlled so as to be in the on state if the voltage of the power supply Vcc is lower than or equal to a predetermined threshold value. The switch VccSW is controlled so as to be in the off state if the voltage of the power supply Vcc exceeds the predetermined threshold value. The predetermined threshold value is, for example, the maximum driving voltage of the amplifier unit 101.

The amplifier unit 101 includes the FETs that are cascode-connected to each other (not illustrated), as in the second embodiment described above with reference to FIG. 8. The number of stacks of the FETs is determined so that the breakdown voltage is ensured at the maximum voltage applied from the power supply Vcc. In other words, the number of stacks is determined so as not to cause breakdown even if the maximum voltage is applied. The amplifier unit 101 includes a resistor divider circuit (not illustrated) for generating the bias to be applied to the gate of the FET of each stage, as in the second embodiment described above with reference to FIG. 8.

Accordingly, the power amplifier circuit 100c includes the amplifier unit 101, which amplifies the radio-frequency signal that is inputted, and the switch VccSW provided on the power supply path to the amplifier unit 101. The power is supplied to the amplifier unit 101 via the switch VccSW. The switch VccSW sets the power supply to the amplifier unit 101 to ON or OFF. As in the second embodiment described above with reference to FIG. 8, the amplifier unit 101 includes an input terminal into which a signal to be amplified is inputted, a first FET having the gate to which the signal inputted into the input terminal is applied, a second FET connected between the power supply and the reference potential with the first FET, and an output terminal that is provided between the second FET and a load and that outputs the amplified signal. The first FET is cascode-connected to the second FET. The relationship between the respective voltage values is the same as that described above with reference to FIG. 9.

The power amplifier circuit 100c illustrated in FIG. 21 operates in the following manner. Specifically, in the power amplifier circuit 100c, when the switch VccSW is set to the on state, the voltage of the power supply Vcc is supplied to the amplifier unit 101. This causes the amplification operation of the amplifier unit 101. The amplifier unit 101 amplifies the signal inputted into the input terminal Tin and outputs the amplified signal from the output terminal Tout. When the switch VccSW is set to the off state, the voltage of the power supply Vcc is not supplied to the amplifier unit 101. At this time, the amplification operation by the amplifier unit 101 is not performed.

In the power amplifier circuit 100c, the amplifier unit 101 may be formed on a silicon die. The silicon die means a die made of Si and is, for example, a die using a Silicon-on-Insulator (SOI) substrate. Also, when the amplifier unit 101 is composed of multiple transistors stacked on the silicon die, it is possible to suppress the maximum voltage applied to the power amplifier circuit to prevent the degradation of the characteristics of the power amplifier circuit while ensuring the breakdown voltage.

### Communication apparatus

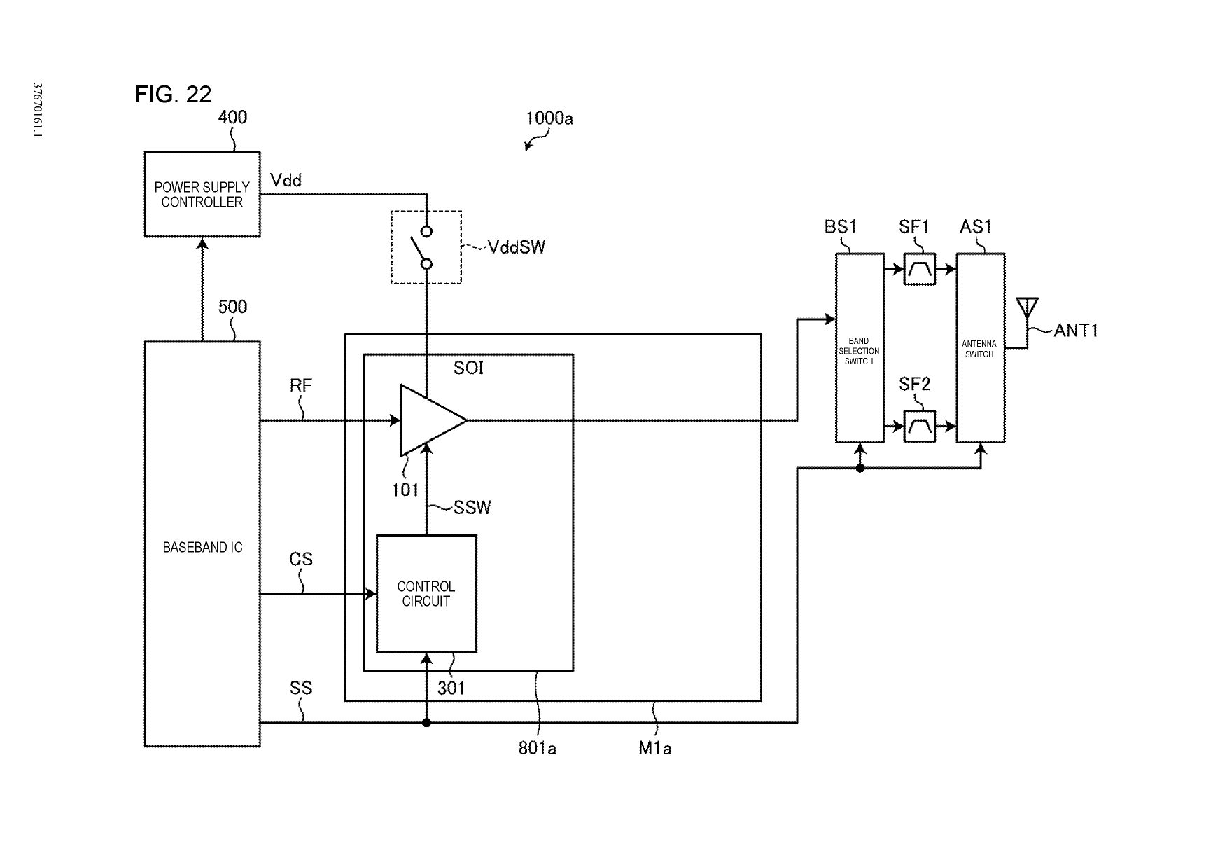

A communication apparatus including the power amplifier circuit 100c will now be described. FIG. 22 is a diagram illustrating an example of the configuration of a communication apparatus 1000a including the power amplifier circuit 100c. The communication apparatus 1000a has only one output system to the antenna, unlike the communication apparatus 1000 described above with reference to FIG. 4. Specifically, the communication apparatus 1000a includes a power amplifier circuit M1a, the band selection switch BS1, the filters SF1 and SF2, the antenna switch AS1, the antenna ANT1, the power supply controller 400, the baseband IC 500, and the switch VddSW. The switch VddSW corresponds to the switch portion of the present disclosure.

The power amplifier circuit M1a is a power amplifier (PA) module and has a function as a power amplifier circuit. The power amplifier circuit M1a includes the amplifier unit 101 and the control circuit 301.

An output end of the amplifier unit 101 is inputted into the band selection switch BS1 as the output from the power amplifier circuit M1a. The control circuit 301 is a circuit that outputs a control signal for controlling the amplifier unit 101. For example, the control circuit 301 supplies the gate bias control signal SSW to the amplifier unit 101. The amplifier unit 101 and the control circuit 301 are realized by, for example, an SOI substrate 801a. The other components in FIG. 22 and the operation are the same as those of the communication apparatus 1000 described above with reference to FIG. 4.

As for the description of the claims, the present disclosure may be embodied by the following aspects.

<1> A power amplifier circuit including amplifier units of multiple stages, the power amplifier circuit comprising: a first amplifier unit configured to amplify a radio-frequency signal that is input; a second amplifier unit configured to amplify an output from the first amplifier unit; and a switch portion configured to be provided on a power supply path to the first amplifier unit, wherein power is supplied to the first amplifier unit via the switch portion, wherein the switch portion sets power supply to the first amplifier unit to ON or OFF, and wherein the power is directly supplied to the second amplifier unit not via the switch portion.

<2> The power amplifier circuit described in <1>, wherein the first amplifier unit is formed on a silicon die, and wherein the second amplifier unit is formed on a die other than the silicon die.

<3> The power amplifier circuit described in <1> or <2>, further comprising: a power supply configured to supply power to the first amplifier unit and the second amplifier unit, wherein the switch portion includes a P-type metal-oxide-semiconductor transistor having a source connected to the power supply, and an N-type metal-oxide-semiconductor transistor having a drain connected to the power supply, wherein a drain of the P-type metal-oxide-semiconductor transistor is connected to a source of the N-type metal-oxide-semiconductor transistor and power is supplied to the first amplifier unit from a node between the drain of the P-type metal-oxide-semiconductor transistor and the source of the N-type metal-oxide-semiconductor transistor, wherein the P-type metal-oxide-semiconductor transistor is in an off state if voltage of the power supply exceeds a predetermined threshold value and is in an on state if the voltage of the power supply is lower than or equal to the predetermined threshold value, and wherein gate bias at which source voltage of the N-type metal-oxide-semiconductor transistor is lower than a predetermined threshold value when the P-type metal-oxide-semiconductor transistor is in the off state is applied to the N-type metal-oxide-semiconductor transistor regardless of the voltage value of the power supply.

<4> The power amplifier circuit described in <3>, further comprising: a bias circuit configured to apply bias to the P-type metal-oxide-semiconductor transistor, wherein the bias circuit applies the bias, at which the P-type metal-oxide-semiconductor transistor is set to the off state if the voltage of the power supply exceeds the predetermined threshold value and is set to the on state if the voltage of the power supply is lower than or equal to the predetermined threshold value, to a gate of the P-type metal-oxide-semiconductor transistor.

<5> The power amplifier circuit described in <4>, further comprising: a comparator configured to compare the voltage of the power supply with predetermined reference voltage, wherein the bias circuit applies the bias to the P-type metal-oxide-semiconductor transistor based on a comparison result in the comparator.

<6> The power amplifier circuit described in <5>, wherein an output signal from the comparator is high-level voltage or low-level voltage, and wherein hysteresis characteristics are given to transition from the high-level to the low-level and transition from the low-level to the high-level.

<7> The power amplifier circuit described in any of <1> to <6>, further comprising: a choke coil configured to be connected in series between the switch portion and the first amplifier unit; and a bypass capacitor configured to be provided between the choke coil and reference potential.

<8> The power amplifier circuit described in any of <1> to <7>, wherein the first amplifier unit includes an input terminal into which a signal to be amplified is inputted, a first field effect transistor having a gate to which the signal inputted into the input terminal is applied, a second field effect transistor configured to be connected between a power supply and reference potential with the first field effect transistor, an output terminal configured to be provided between the second field effect transistor and a load to output a signal that is amplified, and a resistor divider circuit for generating bias to be applied to a gate of the second field effect transistor, and wherein the first field effect transistor is cascode-connected to the second field effect transistor by connecting a drain to an adjacent source.

<9> The power amplifier circuit described in any of <1> to <8>, wherein a power supply voltage value is varied in accordance with output power from the power amplifier circuit.

<10> A power amplifier circuit including an amplifier unit of only one stage, the power amplifier circuit comprising: a first amplifier unit configured to amplify a radio-frequency signal that is input; and a switch portion configured to be provided on a power supply path to the first amplifier unit, wherein power is supplied to the first amplifier unit via the switch portion, wherein the switch portion sets power supply to the first amplifier unit to ON or OFF, wherein the first amplifier unit includes an input terminal into which a signal to be amplified is inputted, a first field effect transistor having a gate to which the signal inputted into the input terminal is applied, a second field effect transistor connected between a power supply and reference potential with the first field effect transistor, an output terminal provided between the second field effect transistor and a load to output a signal that is amplified, and a resistor divider circuit for generating bias to be applied to a gate of the second field effect transistor, and wherein the first field effect transistor is cascode-connected to the second field effect transistor by connecting a drain to an adjacent source.

11 to 17 FET

20 resistor divider circuit

21 to 26, 31 to 36, R0, R1, R11, R12, Rsw1, Rsw2 resistor

41 to 46 capacitor

100, 100a, 100b, 100c power amplifier circuit

101, 201, 202 amplifier unit

1000, 1000a communication apparatus

ANT1, ANT2 antenna

AS1, AS2 antenna switch

B1 bias circuit

BS1, BS2 band selection switch

C11 bypass capacitor

CMP comparator

500 baseband IC

INV inverter

L11 choke coil

LVS level shift circuit

M1, M1a power amplifier circuit

MN1, MN2 matching circuit

PB PMOS gate bias circuit

RFin input terminal

RFout output terminal

SF1 to SF5 filter

SSW1, SSW2, SW1, SW2 switch

SWa, SWb, SWc switch

VR variable resistor

1. A power amplifier circuit including amplifiers of multiple stages, the power amplifier circuit comprising:
a first amplifier configured to amplify a radio-frequency signal that is input;
a second amplifier configured to amplify an output from the first amplifier; and
a switch on a power supply path to the first amplifier,
wherein a power is selectively supplied to the first amplifier via the switch, and
wherein the power is directly supplied to the second amplifier without passing through the switch.

2. The power amplifier circuit according to claim 1,
wherein the first amplifier is on a silicon die, and
wherein the second amplifier is on a die other than the silicon die.

3. The power amplifier circuit according to claim 1, further comprising:
a power supply configured to supply the power to the first amplifier and the second amplifier,
wherein the switch comprises:
a P-type metal-oxide-semiconductor transistor having a source connected to the power supply, and
an N-type metal-oxide-semiconductor transistor having a drain connected to the power supply,
wherein a drain of the P-type metal-oxide-semiconductor transistor is connected to a source of the N-type metal-oxide-semiconductor transistor and power is supplied to the first amplifier from a node between the drain of the P-type metal-oxide-semiconductor transistor and the source of the N-type metal-oxide-semiconductor transistor,
wherein the P-type metal-oxide-semiconductor transistor is in an OFF state when voltage of the power supply exceeds a predetermined threshold value, and is in an ON state if the voltage of the power supply is lower than or equal to the predetermined threshold value, and
wherein a gate bias at which a source voltage of the N-type metal-oxide-semiconductor transistor is lower than a predetermined threshold value when the P-type metal-oxide-semiconductor transistor is in the OFF state is applied to the N-type metal-oxide-semiconductor transistor regardless of the voltage value of the power supply.

4. The power amplifier circuit according to claim 3, further comprising:
a bias circuit configured to apply a bias to the P-type metal-oxide-semiconductor transistor,
wherein the bias circuit is configured to apply the bias, at which the P-type metal-oxide-semiconductor transistor is set to the OFF state when the voltage of the power supply exceeds the predetermined threshold value and is set to the ON state when the voltage of the power supply is lower than or equal to the predetermined threshold value, to a gate of the P-type metal-oxide-semiconductor transistor.

5. The power amplifier circuit according to claim 4, further comprising:
a comparator configured to compare the voltage of the power supply with a predetermined reference voltage,
wherein the bias circuit is configured to apply the bias to the P-type metal-oxide-semiconductor transistor based on a comparison result in the comparator.

6. The power amplifier circuit according to claim 5,
wherein an output signal from the comparator is a high-level voltage or a low-level voltage, and
wherein hysteresis characteristics are given to transition from the high-level to the low-level, and transition from the low-level to the high-level.

7. The power amplifier circuit according to claim 1, further comprising:
a choke coil connected in series between the switch and the first amplifier; and
a bypass capacitor between the choke coil and reference potential.

8. The power amplifier circuit according to claim 1,
wherein the first amplifier comprises:
an input terminal into which the radio-frequency signal to be amplified is inputted,
a first field effect transistor having a gate to which the radio-frequency signal inputted into the input terminal is applied,
a second field effect transistor connected between a power supply and a reference potential with the first field effect transistor,
an output terminal between the second field effect transistor and a load, and configured to output an amplified signal, and
a resistor divider circuit configured to generate a bias applied to a gate of the second field effect transistor, and
wherein the first field effect transistor is cascode-connected to the second field effect transistor by connecting a drain to an adjacent source.

9. The power amplifier circuit according to claim 1, wherein a voltage value of the supplied power is varied in accordance with output power from the power amplifier circuit.

10. A power amplifier circuit including an amplifier of only one stage, the power amplifier circuit comprising:
a first amplifier configured to amplify a radio-frequency signal that is input; and
a switch on a power supply path to the first amplifier,
wherein power is supplied to the first amplifier via the switch,
wherein the first amplifier comprises:
an input terminal into which the radio-frequency signal to be amplified is inputted,
a first field effect transistor having a gate to which the radio-frequency signal inputted into the input terminal is applied,
a second field effect transistor connected between a power supply and a reference potential with the first field effect transistor,
an output terminal between the second field effect transistor and a load, and configured to output an amplified signal, and
a resistor divider circuit configured to generate a bias applied to a gate of the second FET, and
wherein the first field effect transistor is cascode-connected to the second field effect transistor by connecting a drain to an adjacent source.
